(19) United States
(12) Patent Application Publication
(10) Pub. No.: US 2024/0008294 A1
(43) Pub. Date: Jan. 4, 2024

(54) ORGANIC THIN FILM TRANSISTOR

(71) Applicant: SMARTKEM LIMITED, Greater Manchester (GB)

(72) Inventors: Beverley BROWN, Manchester (GB); Chia-Hung TSAI, Manchester (GB); Dan SHARKEY, Manchester (GB); Alejandro CARRERAS, Manchester (GB); Simon OGIER, Manchester (GB)

(73) Assignee: SMARTKEM LIMITED, Manchester, Greater Manchester (GB)

(21) Appl. No.: 18/037,027

(22) PCT Filed: Nov. 16, 2021
(86) PCT No.: PCT/GB2021/052955

§ 371 Date: May 15, 2023

(30) Foreign Application Priority Data
Nov. 16, 2020 (GB) 2017982.6

(51) Int. Cl. H10K 10/46; H10K 59/123; H10K 59/125; H10K 19/10; H10K 10/84; H10K 85/10

(52) U.S. Cl. CPC H10K 10/484; H10K 59/123; H10K 59/125; H10K 71/13; H10K 10/84; H10K 85/111; H10K 19/10

(57) ABSTRACT

The present invention relates to an organic thin film transistor (OTFT) comprising an organic semiconductor layer (2) arranged between a source terminal (3) and a drain terminal (4). The OTFT further includes a front gate (5) electrode arranged on one side of the organic semiconductor layer and a back gate electrode (6) arranged on the opposite side of the organic semiconductor layer. The front and back gate electrodes are arranged to control the current flow in the organic semiconductor layer upon application of a voltage and the back gate electrode is electrically connected to one of: the front gate electrode and the source terminal. OTFT's according to the present invention, with a connection between the back gate and the source or front gate, exhibit improved turn on voltage stability, lower power consumption and improved bias stress stability compared to single gate and back gate isolated OTFTs.

### TECHNICAL FIELD

The present invention relates to an organic thin film transistor (OTFT) and a method for fabricating an OTFT, in particular an OTFT suitable for application in the backplane of an optical display.

### BACKGROUND

In recent years, there has been significant effort directed at the development of organic semiconducting (OSC) materials in order to produce more versatile, lower cost electronic devices. OSC materials find application in a wide range of devices or apparatus, including organic thin film transistors (OTFTs), organic light emitting diodes (OLEDs), photodetectors, organic photovoltaic (OPV) cells, sensors, memory elements and logic circuits to name just a few. The use of organic semiconductors over inorganic materials has a number of advantages, including their intrinsic mechanical flexibility, low cost and the fact that organic semiconductors can be easily formed in a thin film using simple solution processing techniques, such as spin coating and vacuum vapor deposition, which can be carried out at lower temperatures than for conventional semiconductor TFTs. These characteristics significantly reduce the cost of the manufacturing process and open up a wide range of substrate materials, allowing for the reduction of the weight and cost of devices and a greater variety of applications.

One particularly important application is the use of OTFTs within flat panel display apparatuses, such as liquid crystal display devices, organic electroluminescent display devices, and inorganic electroluminescent display devices, where the OTFTs function as switching devices for controlling an operation of each pixel, and as driving devices for driving pixels. In particular, flat panel display apparatuses use a rectangular array of pixels arranged in rows and columns, where each pixel has at least one transistor that acts as a switch to operate the pixel.

In all such electrical devices, and for display devices in particular, there is a need for OTFTs which have electrical characteristics which are predictable, uniform and stable. One particularly important parameter of a transistor is the turn on voltage
the voltage level where a current starts to flow in the OTFT channel. OTFTs employed as a switch in a display backplane should ideally operate as a perfect switch and require only small voltage swings to switch the device from its off state to the on state. Existing devices often exhibit variation in the turn on voltage with the drain voltage which is detrimental for device performance, where, in particular, large variations would require higher voltage swings on the gate and therefore would result in greater power consumption for the display backplane. Another issue is that, because the OTFTs used in display devices remain in the on state for long periods of time, they must have very high bias stress stability to avoid unwanted image persistence effects on the display.

There is accordingly a need for OTFTs which have improved characteristics and provide enhanced performance when employed in electronic devices. The is a particular need for OTFTs with improved turn on voltage, Vₜₒ, stability and bias stress stability, particularly to improve the performance of display devices incorporating the OTFTs. At the same time, the OTFTs should ideally have a high charge mobility so that switching can happen quickly and the OTFT can be miniaturised with small channel width. Smaller sized OTFTs permit a greater proportion of the display pixel to be used to create contrast in the image, and also can enable higher resolution displays to be made for the same size of screen.

The present invention seeks to make progress in addressing some of the above issues.

### SUMMARY OF THE INVENTION

In a first aspect the invention provides organic thin film transistor (OTFT) comprising: an organic semiconductor layer arranged between a source terminal and a drain terminal, wherein the organic semiconductor layer comprises a small molecule organic semiconductor and an organic binder; a front gate electrode arranged on one side of the organic semiconductor layer and a back gate electrode arranged on the opposite side of the organic semiconductor layer, the front and back gate electrodes arranged to control the current flow in the organic semiconductor layer upon application of a voltage; wherein the back gate electrode is electrically connected to one of: the front gate electrode and the source terminal.

OTFT's according to the present invention, comprising an organic semiconductor layer including a small molecule organic semiconductor and an organic binder, which have a connection between the back gate and the source or front gate, exhibit improved turn on voltage stability, lower power consumption and improved bias stress stability compared to single gate and back gate isolated OTFTs. Furthermore, by selecting whether the back gate is connected to the front gate or source, the properties of the OTFT can be altered, in particular to provide near constant turn on voltage (in the case of back gate to source connected devices) and to provide a memory effect in which a negative turn on voltage is maintained for an extended period of time (in the case of back gate to front gate connected device).

These properties arise due to the chemistry of the organic semiconductor layer, in particular, the presence of the organic binder in the semiconductor layer. The combination of the organic small molecule semiconductor and binder lead to a specific microstructure in the formed OTFT, which influences the operating characteristics of the OTFT. In particular, the composition of the OSC layer, may lead to phase separation of the small molecule semiconductor and the organic binder, leading to a vertical phase separated structure in the OTFT which imparts the specific characteristics described. OTFTs according to the present invention can therefore be configured for specific applications requiring these properties, as described below.

Preferably the organic binder comprises a semiconductor binder with a permittivity, k, in the range 3.4≤k≤8.0.

Preferably the organic semiconductor layer comprises a phase separated structure, with phase separation of the organic small molecule semiconductor and the semiconductor binder. In this way, the phase separation forms high mobility OTFT channels simultaneously in both front and back gate configuration. Preferably the phase separated structure comprises two OTFT channels associated with the front and back gate respectively.

Preferably the OTFT comprises a substrate wherein the back gate electrode is positioned between the substrate and the organic semiconductor layer and the front gate electrode is positioned on the opposing side of the organic semiconductor layer to the substrate.

Preferably the organic semiconductor layer comprises a polycrystalline small molecule organic semiconductor and an organic binder. Preferably the organic binder comprises an organic oligomer or polymer semiconductor binder, more preferably a polymer comprising a triarylamine moiety.

Preferably the OTFT comprises a gate insulator layer formed between the organic semiconductor layer and the front electrode. Preferably the OTFT comprises a sputter resistant layer formed between the gate insulator layer and the front gate electrode. The OTFT preferably further comprises a substrate, wherein the back gate electrode is formed on the substrate; and a base layer comprising a cross-linked organic layer, wherein the base layer is formed on the back gate electrode. The layers of the OTFT may comprise materials as described below.

In a further aspect of the invention there is provided an electronic device comprising an OTFT of the first aspect of the invention. The electronic device may comprises a combination of OTFTs according to any preceding claim in which the front gate electrode is connected to the back gate electrode; and OTFTs according to any preceding claim in which the front gate electrode is connected to the source terminal. In this way both the common and distinct respective advantages of the back gate to front gate (BG-FG) and back gate to source (BG-S) connected OTFTs may be harnessed in the same device. This is particularly advantageous as the two distinct types of OTFT, BG-FG and BG-S, may be manufactured by the same process, with the gate connections only carried out at the end of the process. In this way the manufacturing process is significantly less complex and costly than would be the case where two different fabrication processes were required to produce different types of OTFT with the required characteristics in the electronic device.

In a further aspect of the invention there is provided an active matrix display backplane comprising a plurality of OTFTs according to the first aspect of the invention. The improved voltage turn on stability, lower power consumption and improved bias stability and particularly advantageous when employed in such a display device. The active matrix display backplane may comprise a combination of OTFTs according to any preceding claim in which the front gate electrode is connected to the back gate electrode; and OTFTs according to any preceding claim in which the front gate electrode is connected to the source terminal.

In particular the active matrix display may comprise a plurality of pixel OTFTs arranged in a regular array of rows and columns. Multi-TFT pixels are common in current driven displays such as OLED, micro-LED, or active matrix mini LED backlights. The pixel OTFTs may be arranged in a 2T-1C (2 transistor 1 capacitor) or similar arrangement, comprising a drive OTFT and a switch OTFT. In other examples, the pixel OTFTs may be arranged in more complex OTFT arrangements, which are also common in the field, each comprising at least one switch OTFT and one drive OTFT. The switch OTFT when turned on will charge up the capacitor and this is connected to the gate of the drive OTFT, which then drives the current.

One or more of the pixel OTFTs is arranged to control current to a pixel electrode, where one or more of the pixel OTFTs comprises an OTFT according to any preceding claim in which the back gate electrode is connected to the source terminal. BG-S connected OTFTs according to the present invention have extremely stable voltage turn and therefore are particularly applicable as the drive OTFTs for the pixels in a display backplane. Furthermore, since the drive TFT pixel OTFTs are mostly operated in the on state the improved resistance to bias stress effects is particularly beneficial.

The active matrix display may additionally comprise a driver circuit arranged to provide a voltage to a row or column of pixel OTFTs wherein the driver comprises an OTFT according to any preceding claim in which the front gate electrode is connected to the back gate electrode. The negative turn on voltages of the BG-FG OTFTs is particularly suited to use in driver circuitry where a low off current is required at 0V applied potential to the gate of a transistor within the gate driver circuit.

In a further aspect of the invention there is provided a logic circuit comprising an OTFT according to the first aspect of the invention wherein the back gate is electrically connected to the front gate. The logic circuit may comprise a shift register that could form part of the row driver circuitry of a display backplane for example. The negative turn on voltage may be harnessed to reduce power consumption in such circuitry.

In a further aspect of the invention there is provided a method of operating an OTFT according to the first aspect of the invention, wherein the back gate is electrically connected to the front gate, the method comprising: performing a conditioning routine in which a bias is applied to the OTFT to place the OTFT in a temporary condition in which the turn on voltage is negative; and operating the electronic device while the OTFT is in the temporary condition. Applying an initial bias signal to the OTFT places the OTFT into the negative Vₜₒ state, allowing the device to be subsequently operated while the memory effect persists.

The method may comprise performing the conditioning routine again after a predetermined time has elapsed in which the OTFT is not active. In this way, after the memory effect elapses, the device can reconditioned by performing the conditioning routine again. The predetermined time may be between 5 minutes and 2 hours, preferably between 20 minutes and one hour.

In a further aspect of the invention there is provided a method of fabricating an OTFT, the method comprising the steps: forming a back gate electrode on a substrate; forming a source terminal and a drain terminal; forming an organic semiconductor layer above the back gate and between the source and drain terminals; forming a front gate electrode above the organic semiconductor layer; and forming an interconnect to connect the back gate electrode to one of: the front gate electrode and the source terminal.

Forming a back gate electrode on the substrate may comprise sputtering a metal film onto the substrate and etching the metal film to form the back gate electrode. The method may comprise forming an organic cross-linked base layer on the surface of the back gate electrode and forming the drain terminal and the source terminal on the base layer.

Forming an interconnect may comprise forming a passivation layer to cover the front gate electrode and all layers between the front gate electrode and substrate; and etching a plurality of vias through the passivation layer and depositing a metal layer to provide a connection between: the front gate electrode and back gate electrode; or the back gate electrode and source terminal. In particular, to form a BG-FG OTFT the method may comprise etching a first via through the passivation layer to the front gate electrode; etching a second via through the passivation layer to the back gate electrode; and depositing a metal layer to connect the front gate electrode and back gate electrode. To form a BG-S OTFT the method may comprise: etching a first via through the passivation layer to the back gate electrode; etching a second via through the passivation layer to the source terminal; depositing a metal layer to connect the back gate terminal and source electrode. Vias may be formed individually or simultaneously according to the specific design. Preferably the vias are formed simultaneously as it is less costly to process.

### BRIEF DESCRIPTION OF THE DRAWINGS

Embodiments of the invention will now be described, by way of example only, with reference to the accompanying drawings, in which:

FIG. 1A schematically illustrates a front gate to back gate (BG-FG) connected dual gate OTFT according to the present invention;

FIG. 1B schematically illustrates a source to back gate (BG-S) connected dual gate OTFT according to the present invention;

FIG. 1C schematically illustrates an isolated back gate (IBG) dual gate OTFT according to a comparative example;

FIGS. 2A to 2C illustrate the I-V transfer curves of the devices of FIGS. 1A to 1C respectively; and

FIG. 3 schematically illustrates the active matrix of a display backplane according to the present invention.

### DETAILED DESCRIPTION

Overview of Device Structure

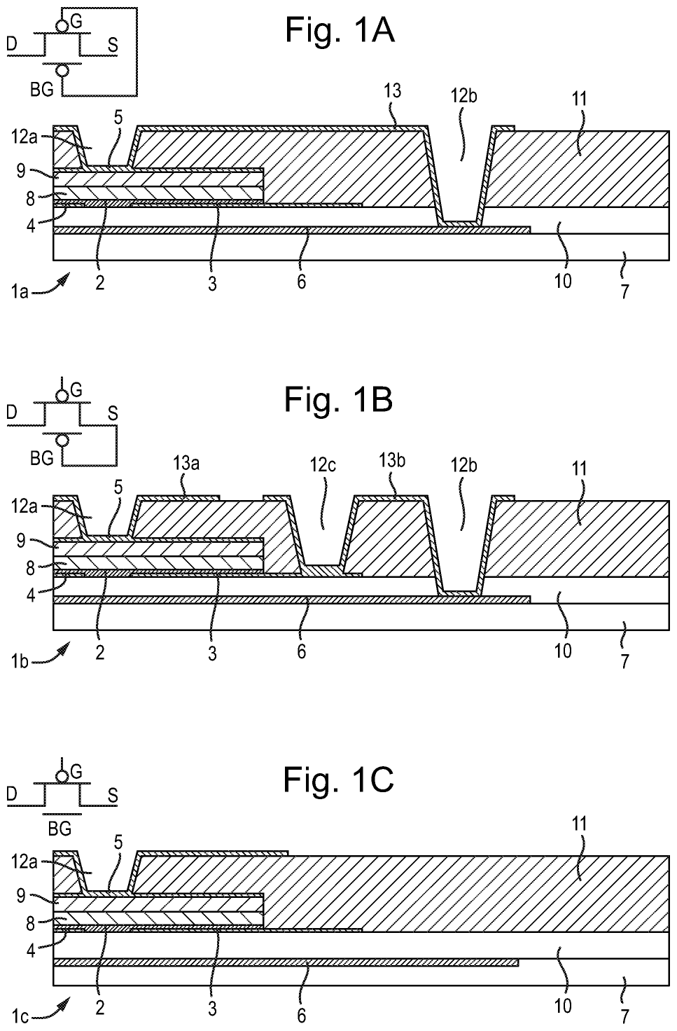

FIGS. 1A and 1B each schematically illustrate an organic thin film transistor (OTFT) 1 according to the present invention. The OTFTs each comprise an organic semiconducting (OSC) layer 2 arranged between a source terminal 3 and a drain terminal 4. The OTFTs each include a front gate electrode 5 arranged on one side of the OSC 2 and a back gate electrode 6 arranged on the opposite side of the OSC 2, where the application of a suitable voltage to the front 5 and/or back gate electrode 6 may be used to control the current flow in the semiconductor layer 2 between the source 3 and drain 4. The OTFTs 1 according to the present invention are characterised in that they have an electrical connection between the back gate electrode 6 and either the front gate electrode 5 (as in the case of the OTFT 1 of FIG. 1A) or the source terminal 3 (as shown in FIG. 1B). This connection between the back gate 6 and the source 3 or front gate 5 provides improved turn on voltage stability, lower power consumption and improved bias stress stability compared to back gate isolated OTFTs, such as that illustrated in the comparative example of FIG. 1C. The improvements provided by the present invention are demonstrated below.

The OTFTs 1a, 1b according to the present invention preferably comprise a number of additional layers selected to improve the performance of the device. The OTFTs 1a, 1b are formed on a substrate 7, generally glass or polymer, where the back gate electrode 6 is defined as the electrode lying under the OSC channel 2, closest to the substrate 7. The back gate electrode 6 in these examples is deposited directly on the substrate 7. A dielectric base layer 10 is positioned above the back gate 6 to isolate the back gate electrode 6 and to facilitate deposition of the OSC layer onto the base layer 10. The chemistry of the base layer 10 is preferably matched to the OSC 2 to allow for uniform OSC layer 2 morphology. The source 3 and drain 4 electrodes are positioned on the base layer 10, separated by a distance L corresponding to the channel length. As shown in FIGS. 1A and 1B the OSC layer 2 is positioned over the source 3 and drain 4 electrodes such that it fills the intervening distance L to form the channel.

In the examples of FIGS. 1A and 1B, two organic dielectric layers 8, 9 are provided separating the OSC layer 2 from the front gate electrode 5. Firstly, an organic gate insulator (OGI) layer 8 is provided directly on the OSC layer 2. The selection of the OGI layer material and its associated permittivity determines carrier density in the channel and influences device hysteresis. A second organic dielectric layer in the form of a sputter resistance layer (SRL) 9 is positioned over the OGI layer 8 which is arranged to provide resistance to the OGI 8 and OSC 2 layers to sputter damage during formation of the gate electrode 5. The SRL layer 9 is also preferably selected to enable the deposition of a wide range of gate electrode materials.

The exemplary devices of FIGS. 1A and 1B further comprise a passivation layer (PL) 11 to seal the layers of the OTFT and provide chemical resistance and physical integrity to the device. A plurality of vias 12a, 12b, 12c are provided within the passivation layer, extending from a top surface of the passivation layer down to a particular terminal to which a connection is to be made. The connections between the terminals are achieved with metal interconnect layers 13, 13a, 13b which provide the required connections between the electrodes for a particular device architecture.

In particular, the back gate to front gate (BG-FG) OTFT 1a of FIG. 1A comprises a first via 12a, extending from an upper surface of the passivation layer 11 to the front gate electrode, and second via 12b, extending from the top of the passivation layer 11 to the back gate electrode 6, where the electrodes are connected by a metal interconnect layer 13 to provide the required connection.

The back gate to source (BG-S) connected OTFT 1b of FIG. 1B comprises a first via 12a, extending from an upper surface of the passivation layer 11 to the front gate electrode, a second via 12b, extending from the top of the passivation layer 11 to the bottom gate electrode 6, and a third via 12c extending from the top of the passivation layer 11 to the source terminal 3. The BG-S OTFT 1b comprises a metal interconnect layer 13b to provide the required connection between the back gate terminal and source terminal 3 and a metal contact layer 13a for the front gate contact.

The length L of the channel 2 between the source 3 and drain 4 is preferably less than 10 μm, more preferably less than 5 μm. The advantages in terms of improved turn on voltage stability, lower power consumption and improved bias stress stability are particularly enhanced at channel lengths of this range. At longer channel lengths, current output increases, and the beneficial effects are less pronounced. The organic gate insulator (OGI) 8 should preferably be low permittivity to ensure a good charge mobility in the channel 2.

For the purpose of providing a comparative example, FIG. 1C illustrates a OTFT 1c, which does not form part of the present invention, in which the back gate electrode 6 is isolated.

Specific details of the materials which can be implemented in each of the layers of the OTFTs 1a, 1b according to the invention and details of methods of fabricating the OTFTs are provided below. First the advantages of the OTFTs of the present invention are explained in the context of their application in electronic devices, in particular within the back plane of a display device.

The inventors have determined that by using a four terminal OTFT, comprising a back gate and a top gate, and by connecting the back gate to another terminal, in particular the source or front gate, the OTFT displays marked improvement in device operation. In particular OTFTs according to the present invention display improved turn on voltage (Vₜₒ) stability, lower power consumption (due to lower gate voltage swing) and improved bias stress stability.

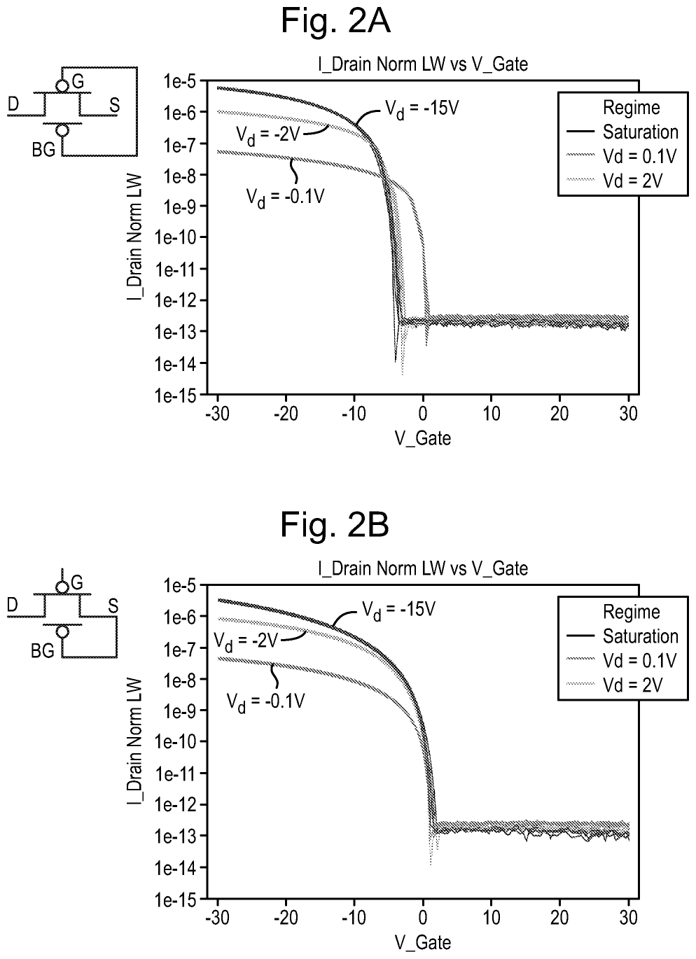

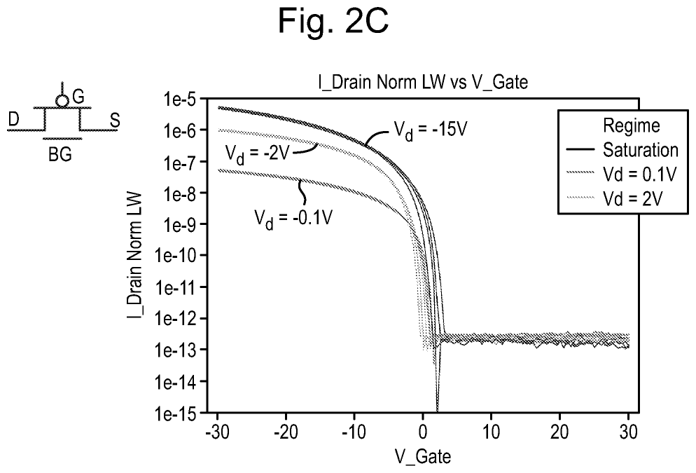

FIGS. 2A to 2C show the transfer curves for the devices of FIG. 1A to 1C respectively. To measure the series of transfer curves shown in FIGS. 2A to 2C, a drain voltage was applied continuously to the OTFT at Vd=−0.1, and then the gate voltage was swept from +30V to −30V in 0.5V steps whilst measuring the drain current. This was repeated for drain voltages of −2V and −15V. This produced 3 separate transfer curves, one at each drain voltage. The source was biased at 0V throughout the measurements.

As can be seen by comparing the transfer curves of the BG-FG OTFT 1a and BG-S OTFT 1b in FIGS. 2A and 2B with the isolated back gate (IBG) OTFT 1c of the comparative example shown in FIG. 2C, the OTFTs 1a, 1b according to the present invention display a marked improvement in voltage turn on (Vₜₒ) stability with changing drain voltage.

In addition to the common advantages and improvements in device performance shared by the OTFTs 1a, 1b according to the present invention. The BG-FG OTFT 1a and BG-S OTFT 1b of FIGS. 1A and 1B also display differing respective advantages which may be harnessed in different applications.

In particular, the BG-S OTFT of FIG. 1B displays a turn-on voltage Vₜₒ which is almost independent of drain voltage, as shown in FIG. 2B, where the Vₜₒ at each V_{d} are each at an almost identical gate voltage, slightly positive of 0V. This is a marked improvement over a corresponding dual gate device in which the back gate 6 is isolated, as shown by the transfer curves of a back gate isolated device in FIG. 2C. BG-S OTFTs 1b according to the present invention are therefore particularly applicable in circuits requiring very predictable current output, such as the switch OTFTs for controlling the pixels of a display backplane, as described below.

The BF-FG OTFT 1a according to the present invention displays a different operating characteristic in the form of a memory effect in which, after the initial transfer curve is recorded in which a positive Vₜₒ is recorded, the BF-FG OTFT 1a retains a negative and almost constant turn-on voltage Vₜₒ for the subsequent transfer curves. The inventors have determined that, after application of an initial gate voltage, BF-FG OTFTs 1a according to the present invention retain a negative turn on voltage Vₜₒ for a period of at least 40 minutes. This effect is particularly beneficial in applications where a low off current is required at V_{g}=0V, for example in logic circuitry. It should be noted that after the change to a negative Vₜ induced by the application of a suitable voltage, the BG-FG also displays voltage turn on stability, albeit to a slightly lesser extent, so shares this characteristic with the BG-S OTFT 1b.

The improved characteristics of the OTFTs 1a, 1b according to the present invention can be harnessed within a wide range of electronic devices to provide improved performance.

Display Device

One such application in which the improved characteristics of the OTFTs according to the present invention can be exploited is within flat panel display devices.

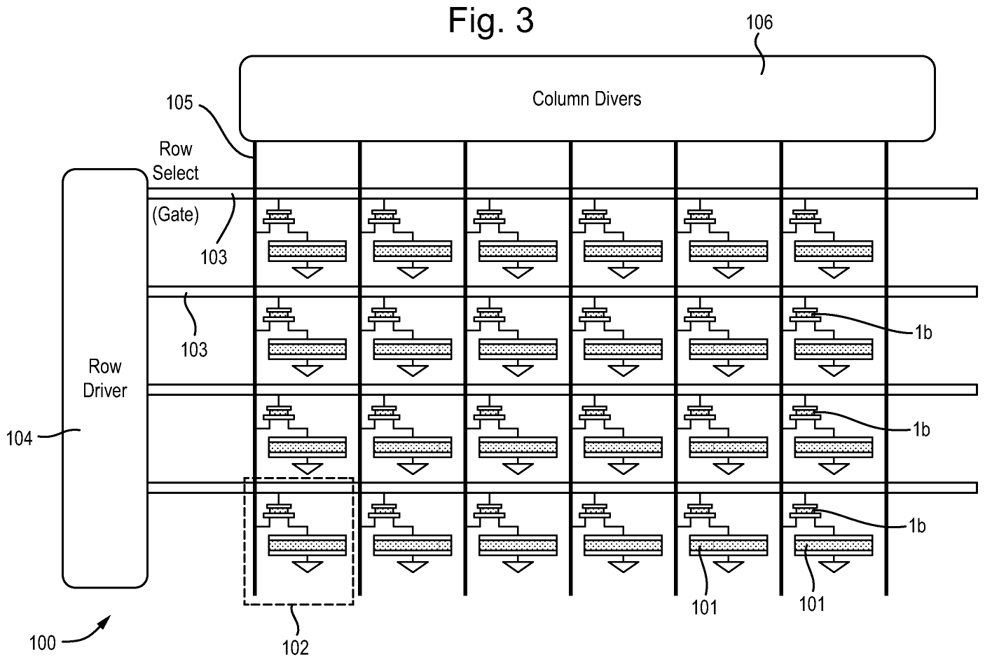

FIG. 3 illustrates a transistor array 100 for a backplane of a display device, where the transistor array comprises an array of OTFTs 1b according to the present invention arranged in a regular array of rows and columns. As in a conventional active matrix display, each OTFT 1b acts as a switch for controlling the application of current to a corresponding pixel capacitor 101, where each pixel 102 may comprise a 1T-1C, 2T-1C or other combination of transistors and capacitors in a pixel circuit. In particular, the back plane comprises a series of row (or gate) lines 103 connected to the gate of each OTFT 1b in a common row, where each row line is connected to a row driver 104 for applying a voltage to the gate of each of the transistors 1b in a particular row. The source or drain terminal of each OTFT 1b in a particular column is connected to a column (or data) line 105. A row driver 106 is connected to each gate line 105 and a column driver 106 is connected to each data line 105. Each pixel 102 is individually addressable by providing a voltage pulse with the row driver 104 to turn on each OTFT 1b in a row while providing the required data voltage to the source or drain terminal of each OTFT to charge the pixel capacitor. By scanning through each row in sequence and applying the data voltages to each data line 105, a data signal can be written into the pixel capacitors of the matrix.

The improved device characteristics of the OTFTs 1a, 1b according to the present invention are particularly beneficial when employed in the active matrix of a display backplane 100. In particular, since the switch OTFT's of the pixels of a display backplane are mostly operated in the on state they must be resistant to bias stress effects. The significantly improved bias stress stability of both the BG-FG OTFT 1a and BG-S OTFT 1b of FIGS. 1A and 1B therefore deliver improved device performance when used in such a device, where they result in reduced image persistence or “ghost image” effects.

Furthermore, the almost independent voltage turn on Vₜₒ of the BG-S OTFTs 1a in particular means they are particularly well suited to application as the pixel OTFTs 1b of an active matrix display 100, where very predictable current output is required to deliver the intended amount of charge to the pixel capacitor 101. On the other hand, the negative turn on voltage of the BF-FG OTFT 1a is particularly beneficial in the gate driver circuitry where it is important to maintain a very low off current when the OTFTs are off. A combination of both BG-FG OTFTs 1a and BG-S OTFTs 1b may therefore be employed in the same device backplane 100 to provide synergistic improvements in the overall device performance.

The negative Vₜₒ for the BG-FG when used in logic circuitry, such as a shift register that could form part of the row driver circuitry for example, could consume less power than a device with a positive Vₜₒ. A circuit might contain one or more OTFTs with a BG-FG connection and one or more OTFTs with a BG-S connection. It may be beneficial for different parts of the circuit to have different Vₜₒ, such as for the generation of so called dual Vₜₕ logic which can have a greater noise margin compared with unipolar single Vₜₕ logic.

Overview of OTFT Fabrication Method

A method of fabricating the OTFTs 1a, 1b according to the present invention involves firstly depositing a back gate electrode 6 on a substrate 7, depositing a dielectric base layer 10 on the back gate 6 and patterning source 3 and drain 4 electrodes on top of the base layer 10. The OSC layer 2 is then deposited to cover the source 3 and drain 4 electrodes and fill an intervening space between the source 3 and drain 4 electrodes to provide the active channel of the device. One or more organic dielectric layers 8, 9 are then deposited over the OSC layer 2 and a front gate layer is patterned to form the front gate electrode 5. A passivation layer 11 is then deposited to enclose the previously deposited layers and a number of vias are patterned in the passivation layer to provide access to the required electrodes, the arrangement of the vias dependent on whether a back gate to front gate (BG-FG) connected OTFT 1a is required (as shown in FIG. 1A) or a back gate to source (BG-S) OTFT 1b (FIG. 1B).

To fabricate the BG-FG OTFT 1a, a first via 12a is etched down to the level of the front gate 5 and a second via 12b is etched down to the level of the back gate 6. A metal layer is then deposited, patterned and etched to for the gate interconnect 13 between the front gate 5 and back gate 6.

To fabricate the BG-S OTFT 1b a first via 12a is etched down to the level of the front gate 5, a second via 12b is etched down to the level of the back gate 6 and a third via 12c is etched down to the level of the source electrode 3. A metal layer is then deposited, patterned and etched to form the front gate contact 13a and the source to back gate interconnect 13b.

OTFT Layer Materials

The characteristics of the dual gate OTFTs according to the present invention may further be optimised by appropriate selection of the materials and morphology of each of the layers in the OTFT stack. The following sets out preferable materials and fabrication methods for each of the layers of the OTFT according to the present invention.

Organic Semiconducting Layer

The organic semiconducting layer of the OTFT according to the present invention comprises a small molecule organic semiconductor and an organic binder. The term “small molecule” takes its normal meaning in field, i.e. a low molecular weight organic compound, for example having a molecular weight up to 900 daltons. The organic semiconductor (OSC) layer of the OTFT according to the present invention preferably comprises at least one semiconducting ink including the small molecule organic semiconductor and the organic binder. Preferably the OSC layer comprises a polycrystalline small molecule organic semiconductor, combined with the organic binder. Preferably the polycrystalline small molecule organic semiconductor comprises a polyacene compound. Preferably the organic binder is an organic semiconductor binder, preferably comprising a triarylamine moiety.

Preferably the organic binder comprises a semiconductor binder with a permittivity, k, in the range 3.4≤k≤8.0.

Preferably, the semiconducting ink comprises a formulation of a discrete polyacene molecule and/or an organic (oligomer/polymer) binder. More preferably, the semiconducting ink forming the OSC layer comprises a polyacene and a polymer binder comprising at least one triarylamine moiety. Said triarylamine moiety preferably contains one or more functional groups selected from the group consisting of CN and C₁₋₄ alkoxy.

In a further preferred embodiment, the semiconducting ink forming the OSC layer comprises a discrete polyacene molecule and a polymer binder, said polymer binder comprising at least one triarylamine moiety and a polyacene moiety.

One specific preferable example of an organic semiconducting layer in an OTFT according to the present invention comprises TMTES pentacene (triethyl(2-{1,4,8,11-tetramethyl-13-[2-(triethylsilyl)ethynyl]pentacen-6-yl}ethynyl)silane) and a binder polymer. The OSC layer may comprise 0.4% wt TMTES pentacene and 0.8% wt binder polymer. The binder polymer of this example preferably comprises one or more of the following three monomer moieties M1, M2 and M3: M1 N,N-Diphenyl(2,4-xylyl) amine

| | | |
|---|---|---|
| M1 | 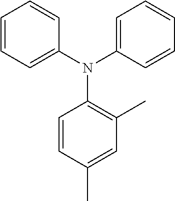 [SMILES: Cc1ccc(N(c2ccccc2)c2ccccc2)c(C)c1] | N,N-Diphenyl(2,4-xylyl) amine |
| M2 | 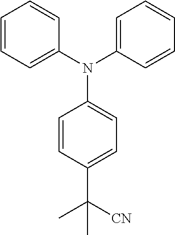 [SMILES: CC(C)(C#N)c1ccc(N(c2ccccc2)c2ccccc2)cc1] | 2-[p(Diphenylamino)phenyl]-2 methylpropiononitrile |
| M3 | 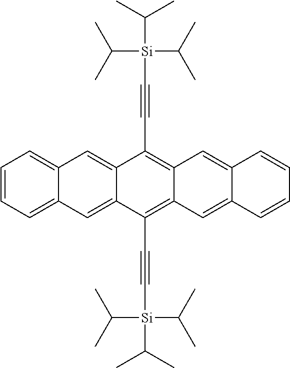 [SMILES: CC(C)[Si](C#Cc1c2cc3ccccc3cc2c(C#C[Si](C(C)C)(C(C)C)C(C)C)c2cc3ccccc3cc12)(C(C)C)C(C)C] | Tris(isopropyl)(2-{13-[2-(tris(isopropylsilyl)ethynyl]pentacen-6- yl})ethynyl]silane (CAS no. 373596-08-08) |

Preferably the binder comprises a random copolymer of the three monomer moieties M1, M2 and M3, preferably by percentage weight 59% M1: 29% M2:10% M3. The binder may be prepared according to patent WO2013/124682.

Although in preferred embodiments a semiconducting organic binder is used together with a discrete small molecule organic semiconductor, an insulating organic binder may equally be used in place of the semiconducting binder.

Suitable insulating binders are described in WO2005/055248. For example the insulating binder may comprise a material selected from selected from poly(α-methylstyrene), polyvinylcinnamate, poly(4-vinylbiphenyl), poly(4-methylstyrene) and Topas™ 8007, more preferably poly(α-methylstyrene), polyvinylcinnamate and poly(4-vinylbiphenyl).

Preferably, the ink comprises a small molecule polyacene and/or polytriarylamine binder formulation. Preferred semiconducting inks include those described in WO2010/0020329, WO2012/003918, WO2012/164282, WO2013/000531, WO2013/124682, WO2013/124683, WO2013/124684, WO2013/124685, WO2013/124686, WO2013/124687, WO2013/124688, WO2013/159863, WO2014/083328, WO2015/028768, WO2015/058827, WO2014/005667 WO2012/160383, WO2012/160382, WO2016/015804, WO2017/0141317, WO2018/078080.

Other organic semiconductor materials that can be used in the OSC layer of the OTFT according to the invention include discrete molecules, oligomers and derivatives of compounds of the following: conjugated hydrocarbon polymers such as of polyacene, acene-thiophene, benzothienobenzothiophene, polyphenylene, poly(phenylene vinylene), polyfluorene, polyindenofluorene including oligomers of those conjugated hydrocarbon polymers; condensed aromatic hydrocarbons such as tetracene, chrysene, pentacene, pyrene, perylene, coronene, diketopyrrolopyrroles, substituted benzothienobenzothiophenes (e.g. C8-BTBT), di-naphthothienothiophenes (DNTT); indacenodithiophenes, or substituted derivatives of these; oligomeric para substituted phenylenes such as p-quaterphenyl (p-4P), p-quinquephenyl (p-5P), p-sexiphenyl (p-6P), or soluble substituted derivatives of these; conjugated heterocyclic polymers such as poly(3-substituted thiophene), poly(3,4-bisubstituted thiophene), polybenzothiophene, polyisothianapthene, poly(N-substituted pyrrole), poly(3-substituted pyrrole), poly(3,4-bisubstituted pyrrole), polyfuran, polypyridine, poly-1,3,4-oxadiazoles, poly-isothianaphthene, poly(N-substituted aniline), poly(2-substituted aniline), poly(3-substituted aniline), poly(2,3-bisubstituted aniline), polyazulene, polypyrene; pyrazoline compounds; polyselenophene; polybenzofuran; polyindole; polypyridazine; benzidine compounds; stilbene compounds; triazines; substituted metallo- or metal-free porphines, phthalocyanines, fluorophthalocyanines, naphthalocyanines, naphthalene diimides or fluoronaphthalocyanines; C60 and C70 fullerenes; N,N′-dialkyl, substituted dialkyl, diaryl or substituted diaryl-1,4,5,8-naphthalene tetracarboxylic diimide and fluoro derivatives; N, N′-dialkyl, substituted dialkyl, diaryl or substituted diaryl-3,4,9,10-perylene-tetracarboxylic-diimide; polynaphthalene diimide-alt-bithiophene; bathophenanthroline; diphenoquinones; 1,3,4-oxadiazoles; 11,11,12,12-tetracyanonaptho-2,6-quinodimethane; [alpha],[alpha]′-bis(dithieno[3,2-b2′,3′-d]thiophene); dithieno[2,3-d;2′,3′-d′]benzo[1,2-b;4,5-b′]dithiophene (DTBDT); poly dithienobenzodithiophene-co-diketopyrrolopyrrolebithiophene(PDPDBD); iso-indigo-bithiophene-(IIDDT-C3), thieno[3,2-b]thiophene-5-fluorobenzo[c][1,2,5]thiadiazole copolymers, di(thiophen-2-yl)thieno[3,2-b]thiophene (DTTT); 2,8-dialkyl, substituted dialkyl, diaryl or substituted diaryl anthradithiophene; 2,2′-bibenzo[1,2-b:4,5-b′]dithiophene, benzothienobenzothiophene (BTBT) polymers benzodithiazole polymers, and mixtures thereof.

Preferred compounds are those from the above list and derivatives thereof which are soluble.

Organic Gate Insulator (OGI) Layer

The OTFT according to the present invention preferably comprises an OGI layer formed over the OSC layer. The OGI layer is preferably selected to improve charge transport in the OSC channel. Providing an OGI as defined herein improves device performance such as higher frequency switching, higher current driving ability and reduces device hysteresis.

The OGI layer of the OTFT according to the preferably invention preferably comprises a material as described in WO 2020/002914.

The OGI layer of the OTFT according to the preferably invention preferably comprises a dielectric material having a dielectric constant (k)<3.0 @ 1000 Hz. The OGI layer material is preferably selected from the group consisting of perfluoropolymers, benzocyclobutene polymers (BCB), parylene, polyvinylidene fluoride (PVDF) polymers, cyclic olefin copolymers (e.g. norbornene, TOPAS™), perfluoro cyclic olefin copolymers (e.g. norbornene, TOPAS™), perfluoro cyclic olefin polymers, adamantyl polymers, perfluorocyclobutylidene polymers (PFCB), siloxane polymers (such as polymethylsiloxane), and mixtures thereof, preferably perfluoropolymers.

The OGI layer material preferably contains a repeat unit selected from the group:

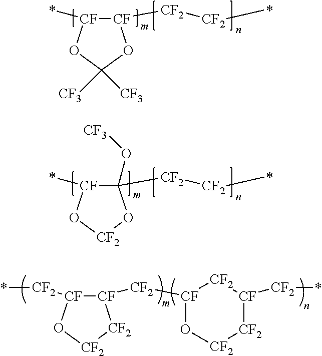

wherein * indicates the point of attachment of the repeat unit to the rest of the polymer and m and n are integers.

The OGI layer is preferably arranged to have a surface free energy of 15-22 mN/m, preferably <15 mN/m.

Preferred amorphous perfluorinated polymers are available from Du Pont (Teflon® AF), Asahi Glass (as Cytop®), and Solvay (as Hyflon® AD). Teflon® AF and Hyflon® AD are copolymers of 2,2-bis(trifluoromethyl)-4,5-difluoro-1,3-dioxole (I) and 2,2-bis(trifluoromethyl)-4-fluoro-5-trifluoromethoxy-1,3-dioxole (II) with tetrafluoroethylene, respectively. Cytop® 809M is a most preferred OGI material for use in the present invention.

Sputter Resistant Layer (SRL)

In some preferable examples of the invention, the OTFT further comprises a sputter resistant layer (SRL) over the OGI layer. The SRL provides resistance of the OGI and OSC to sputter damage during fabrication, resulting in OTFTs with improved characteristics and more uniform performance between devices. The SRL further enables deposition of a wide range of gate materials.

The SRL preferably comprises a cross-linked organic layer as described in WO 2020/002914. The cross-linked organic layer is preferably obtainable by polymerisation of a solution comprising at least one non-fluorinated multi-functional acrylate, a non-acrylate organic solvent, a cross-linkable fluorinated surfactant and a silicone surfactant, where the silicone surfactant is preferably a cross-linkable silicone surfactant and may be a non-fluorinated surfactant. The silicone surfactant may be an acrylate- and/or methacrylate-functionalised silicone surfactant.

The SRL preferably has a cross-link density in the range of 3H to 6H pencil hardness.

The SRL preferably comprises a cross-linked organic layer having a permittivity (k)>3.3 @ 1000 Hz, more preferably the cross-linked organic layer has a k>4.0 at 1000 Hz. Preferably the cross-linked organic layer thereon is 50-4000 nm thick, preferably 100-500 nm thick, more preferably 100-350 nm thick. The surface free energy of the cross-linked-organic layer is preferably between 16-35 mN/m, preferably 18-35 mN/m, preferably 20-35 mN/m, preferably 22-27 mN/m. The permittivity of the cross-linked organic layer is preferably >4, preferably between 4 to 10 @ 1000 Hz.

The OTFT according to the present invention may comprise an SRL comprising more than one cross-linked organic layer.

Substrate and Base Layer

The OTFT according to the present invention preferably comprises a substrate which is preferably transparent. The substrate may preferably comprise glass or polymer. The back gate electrode is preferably deposited directly onto the substrate. The OTFT preferably comprises a base layer formed on the back gate electrode to insulate the back gate electrode and provide a suitable surface for forming the OSC layer. The use of a base layer as defined herein allows for highly uniform OSC layer morphology to be formed, even over large areas.

The base layer is preferably an organic cross-linked layer, where the chemistry is preferably selected such that it is free from residual ionic contamination that may dope the OTFT under bias stress conditions. The base layer may be an acrylate polymer. Suitable base layer materials may be selected from those described in WO 2020/002914. The base layer may have a thickness of 10 nm to 10 μm, preferably 100 nm to 1 μm. The base layer is preferably resistant to organic solvents.

An adhesion layer, such as an epoxy primer, may be formed on the back gate electrode with the base layer then deposited on the adhesion layer.

### Examples

### Fabrication of an OTFT According to the Present Invention

1. Preparation of Substrate

A Corning Eagle XG glass substrate was used for the fabrication. The glass was cleaned by sonication in a 1% Deconex solution at 50° C. for 1 hour followed by DI water rinsing and drying with an air gun, followed by baking at 70° C. for 60 minutes.

2. Forming Back Gate Electrode

A metal film consisting of 3 layers was sputtered onto the glass consisting of 12 nm Molybdenum, 46 nm Aluminium and 70 nm Molybdenum using an MRC sputter system. The layer of metal was patterned to form the back-gate contact of the transistors using photolithography and wet chemical etching (Phosphoric-Acetic-Nitric acid in water).

3. Depositing a Base Layer After the resist was removed using flood exposure and development, a thin (˜nm) adhesion layer (SmartKem product epoxy primer) was deposited by flooding for 2 minutes followed by spin coating at 1000 rpm for 20 s and hot-plate baking at 100° C. for 1 minute.

On to this a base-layer (BL) of acrylate polymer (SmartKem product XSL-01-01-00) was spin coated, UV cured at 4200 mJ/cm2 using a broadband wavelength mercury lamp (g/h/i line) whilst under N2 flow and then baked at 180° C. for 60 minutes. The film was measured at 500 nm after crosslinking.

4. Forming Source and Drain Terminals Onto the BL a 50 nm layer of Au was sputtered and patterned with photolithography and wet-etching (KI/I in water) to form the source-drain electrodes of the transistors.

After stripping the photoresist with flood expose and develop, the sample was cleaned in a PE100 plasma system using O2/Ar mixed gas plasma (250 W, 65 s) then a self-assembled monolayer (SAM) was formed by depositing an IPA solution of SAM (SmartKem product XSM-04-01-01) onto the electrodes for 1 minute followed by spin coating at 1000 rpm for 20 s.

This was followed by 2 cycles of flooding the sample with IPA followed by spin coating to rinse off any excess SAM material. The substrate was baked at 100° C. for 1 minute followed by cooling to room temperature for 1 minute.

5. Depositing the Organic Semiconductor Layer

After this a layer an organic semiconductor formulation comprising 0.4% wt TMTES pentacene (triethyl(2-{1,4,8,11-tetramethyl-13-[2-(triethylsilyl)ethynyl]pentacen-6-yl}ethynyl)silane) and 0.8% wt a binder polymer.

The binder polymer used (Poly[{N,N-Diphenyl(2,4-xylyl) amine}-co-{2-[p(Diphenylamino)phenyl]-2 methylpropiononitrile}-co-{Tris(isopropyl)(2-{13-[2-(tris(isopropylsilyl)ethynyl]pentacen-6-yl})ethynyl]silane}]) is a random copolymer comprising three monomer moieties M1, M2 and M3 by percentage weight 59% M1: 29% M2:10% M3 prepared according to patent WO2013/124682).

| | | |
|---|---|---|
| M1 | 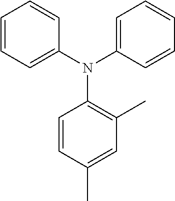 [SMILES: Cc1ccc(N(c2ccccc2)c2ccccc2)c(C)c1] | N,N-Diphenyl(2,4-xylyl) amine |
| M2 | 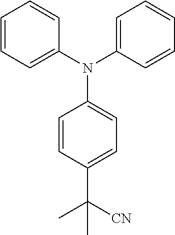 [SMILES: CC(C)(C#N)c1ccc(N(c2ccccc2)c2ccccc2)cc1] | 2-[p(Diphenylamino)phenyl]-2 methylpropiononitrile |
| M3 | 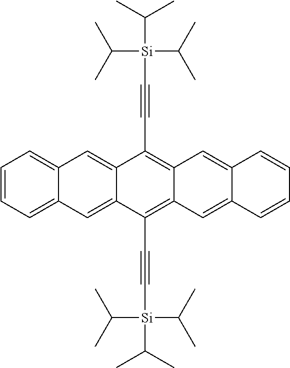 [SMILES: CC(C)[Si](C#Cc1c2cc3ccccc3cc2c(C#C[Si](C(C)C)(C(C)C)C(C)C)c2cc3ccccc3cc12)(C(C)C)C(C)C] | Tris(isopropyl)(2-{13-[2-(tris(isopropylsilyl)ethynyl]pentacen-6- yl})ethynyl]silane (CAS no. 373596-08-08) |

These materials were formulated in tetralin and spin coated on a co-rotating Suss spin coater at 500 rpm for 10 s followed by 1250 rpm for 60 s. The sample was immediately baked at 100° C. for 1 minute.

6. Forming the Organic Gate Insulator Layer A first organic gate dielectric layer of 150 nm thickness (Cytop 809M diluted to 3% wt in FC43 solvent) was spin coated at 1500 rpm for 20 s followed by baking at 50° C. for 1 minute and then 100° C. for 1 minute.

7. Depositing the Sputter Resistant Layer

Following this a second organic gate dielectric layer (SmartKem acrylate product XSL-01-02-01) was deposited and spin coated at 500 rpm for 10 s followed by 1250 rpm for 180 s and UV cured at 4200 mJ/cm2 using a broadband wavelength mercury lamp (g/h/i line) whilst under N2 flow and then baked at 120° C. for 5 minutes.

The layer thickness was measured at 400 nm for the second dielectric layer which forms the sputter resistant layer.

8. Forming the Front Gate Layer

After this a gate layer (50 nm Au) was sputtered and patterned with photolithography and wet-etching (KI/I in water) to form the gates electrode of the transistors.

The resist was removed by flood exposure and development. The sample was then reactive ion etched (Oxford Plasma lab 800+ RIE, 200 mT, 100 sccm O2) to remove the organic layers down to the BL except for the areas covered by the gate electrodes.

A single wavelength end-point detection system was used to determine when the OSC and OGI layers had been etched away in RIE so that the etching could be stopped at the appropriate time.

9. Passivation Layer

After RIE, a passivation layer (PL) (SmartKem acrylate based material PL-02-02-01) was deposited, spin coated and hotplate baked at 100° C. for 1 minute. It was then UV cured at 4200 mJ/cm2 using a broadband wavelength mercury lamp (g/h/i line) whilst under N2 flow and then baked at 120° C. for 5 minutes.

The total thickness of the PL was 2 microns.

10. Connecting the Back Gate Electrode

Vias were patterned in the PL using photolithography and RIE followed by resist flood exposure and development. The RIE etched down the vias to the level of the back-gate metal so that interconnections could be made to this layer.

After this a metal layer (50 nm Au) was sputtered and patterned with photolithography and wet-etching (KI/I in water) to form the gate interconnect wiring for the transistors. Finally the resist was removed by flood exposure and development to allow testing.

10a. Back gate to front gate connected (BG-FG) OTFT design

For the back gate to front gate connected (BG-FG) OTFT design, a first via was etched to the front gate electrode and a second via was etched to the back gate electrode with a connecting metal layer deposited as above to connect the front gate and back gate.

10b. Back gate to source connected (BG-S) OTFT design

For the back gate to source connected (BG-S) OTFT design, a first via was etched to the front gate electrode and a metal connection deposited for the front gate connection. A second via was etched to the back gate electrode and a third via was etched to the source terminal with a connecting metal layer deposited between the second and third vias to connect the source and back gate

10c. Isolated Back Gate (IBG) Comparative Example

As a comparative example a dual gate device was prepared in which the back gate electrode was isolated, with only a front gate connection provided.

Device Testing

Devices were tested using a Wentworth Pegasus S200 semi-automated probe station connected to a Keithley 4200 Semiconductor Parameter Analyser running ACS software. Capacitors on the test substrate were measured using an Agilent E4980A LCR meter at a frequency of 1 kHz. The capacitor values were used in the calculation of mobility from the IV characteristics of the transistor devices. To measure a series of transfer curves, a drain voltage was applied continuously to the transistor at Vd=−0.1, and then the gate voltage was swept from +30V to −30V in 0.5V steps whilst measuring the drain current. This was repeated for drain voltages of −2V and −15V. This produced 3 separate transfer curves, one at each drain voltage. The source was biased at 0V throughout the measurements.

Linear Regime Equation

$$μ = \frac{L}{{WC}_{i} {V}_{d}} \frac{δ {I}_{d}}{δ {V}_{g}}$$

where δI_{d}/δV_{g} is the gradient of the ID-VG plot. Where mobility is gate voltage dependent, the value quoted is the maximum recorded in accumulation with V_{d}<V_{g}. W is the channel width of the transistor, L is the channel length of the transistor, Cᵢ is the capacitance of the gate dielectric and V_{d} is the drain voltage applied to the transistor.

The turn on voltage Vₜₒ was determined as the gate voltage at which 1 pA of current was flowing after scaling the current by W and L to 1/1 microns. Hence, for a W/L of 100/4 the current would be divided by a factor of 100/5=25 to normalise it to W/L of 1/1.

Results

### 1. IBG OTFT (Comparative Example)

The transfer curve for this design is shown in FIG. 2C, shows that the initial scan at V_{d}=−0.1V had a Vₜₒ of +1.0V, for V_{d}=−2V the Vₜₒ was 0.0V, and for V_{d}=−15V the Vₜₒ was +2.1V. Each of these values is an average of 4 transistors with W/L of 177/4. Charge mobility of the devices was 2.5 cm²/Vs in the linear regime. As can be seen from the data, this type of device has a positive turn on voltage and hence a positive gate voltage is required to turn the device off. The turn on voltage varies with drain voltage and hence it is more difficult to design circuits with this type of transistor due to the Vₜₒ depending on the V_{d} value.

### 2. BG-S OTFT

The transfer curves for this design of transistor (FIG. 2B) shows that the initial scan at V_{d}=−0.1V had a Vₜₒ of +1.1 V, for V_{d}=−2V the Vₜₒ was 1.3V, and for V_{d}=−15V the Vₜₒ was +1.4V. Each of these values is an average of 6 transistors with W/L of 177/4. Charge mobility of the devices was 2.2 cm²/Vs in the linear regime.

This type of device has a Vₜₒ that is almost independent of drain voltage. It therefore can be used in circuits that require a very predictable current output.

### 3. BG-FG OTFT

The transfer curves (FIG. 2A) for this design of transistor shows that the initial scan at V_{d}=−0.1V had a Vₜₒ of +0.63V, for V_{d}=−2V the Vₜₒ was −2.8V, and for V_{d}=−15V the Vₜₒ was −2.6V. Each of these values is an average of 13 transistors with W/L of 177/4. Charge mobility of the devices was 2.8 cm²/Vs in the linear regime.

The BG-FG connected device behaviour was studied to determine how long the negative Vₜₒ would persist following the measurement of the first transfer curve. In this test we measured a transfer curve at V_{d}=−2V and then immediately measured another transfer curve at V_{d}=−2V (scan 2). Following this then further transfer curves were measured at a later time to determine the Vₜₒ after the period of relaxing. The following table shows the results for two devices measured on the same substrate.

| Scan time | Vₜₒ [V] |
|---|---|
| Initial scan (device 1) | +1.5 V |
| Immediately following initial scan (2^{nd} scan) | −2.0 V |
| 5 minutes after 2^{nd} scan | −1.5 V |
| 10 minutes after 2^{nd} scan | −1.0 V |
| Initial scan (device 2) | +1.5 V |
| Immediately following initial scan (2^{nd} scan) | −2.0 V |
| 40 minutes after 2^{nd} scan | −0.5 |
| 40 minutes after 3^{rd} scan | −0.5 |
| 1 hour 40 minutes after 4^{th} scan | 0 |

These results show that the negative turn on voltage is retained for a period of at least 40 minutes following the initial scan. This would mean that an electronic system that relies on a negative Vₜₒ for good operation would only have to have a device conditioning routine run for gaps in operation of the device longer than 40 minutes (e.g. at start up or after a 40 minute idle period where the system is not used).

1. An organic thin film transistor, OTFT, comprising:
an organic semiconductor layer arranged between a source terminal and a drain terminal, wherein the organic semiconductor layer comprises a small molecule organic semiconductor and an organic binder;
a front gate electrode arranged on one side of the organic semiconductor layer and a back gate electrode arranged on the opposite side of the organic semiconductor layer, the front and back gate electrodes arranged to control the current flow in the organic semiconductor layer upon application of a voltage;
wherein the back gate electrode is electrically connected to one of: the front gate electrode and the source terminal.

2. The OTFT of claim 1 wherein the small molecule organic semiconductor comprises a polyacene compound.

3. The OTFT of claim 1 wherein the organic binder comprises an organic oligomer or polymer semiconductor binder.

4. The OTFT of claim 3, wherein the organic semiconductor binder comprises a polymer comprising a triarylamine moiety.

5. The OTFT of claim 1 wherein the organic semiconducting layer comprises a semiconducting ink, the semiconducting ink comprising a polyacene compound and the organic binder, where the organic binder is a polymer binder comprising at least one triarylamine moiety.

6. The OTFT of claim 4 wherein the triarylamine moiety contains one or more functional groups selected from the group consisting of CN and C₁₋₄ alkoxy.

7. The OTFT of claim 1 wherein the organic binder comprises a semiconducting binder with a permittivity, k, in the range 3.4≤k≤8.0.

8. The OTFT of claim 1 wherein the organic binder comprises an insulating binder, wherein the insulating binder comprises a material selected from selected from poly(α-methylstyrene), polyvinylcinnamate, poly(4-vinylbiphenyl), poly(4-methylstyrene) and Topas™ 8007, more preferably poly(α-methylstyrene), polyvinylcinnamate and poly(4-vinylbiphenyl).

9. The OTFT of claim 1 comprising a substrate wherein the back gate electrode is positioned between the substrate and the organic semiconductor layer and the front gate electrode is positioned on the opposing side of the organic semiconductor layer to the substrate.

10. The OTFT of claim 1 comprising a gate insulator layer formed between the organic semiconductor layer and the front gate electrode.

11. The OTFT of claim 10, wherein the gate insulation layer comprises a material selected from the group consisting of perfluoropolymers, benzocyclobutene polymers (BOB), parylene, polyvinylidene fluoride (PVDF) polymers, cyclic olefin copolymers (e.g. norbornene, TOPAS™), perfluoro cyclic olefin polymers, adamantyl polymers, perfluorocyclobutylidene polymers (PFCB), siloxane polymers (such as polymethylsiloxane), and mixtures thereof, preferably perfluoropolymers.

12. The OTFT of claim 10 comprising a sputter resistant layer formed between the gate insulator layer and the front gate electrode, wherein the sputter resistant layer comprises a cross-linked organic layer having a permittivity (k)>3.3 @ 1000 Hz.

13. The OTFT of claim 1 comprising:
a substrate, wherein the back gate electrode is formed on the substrate;
a base layer comprising a cross-linked organic layer, wherein the base layer is formed on the back gate electrode.

14. The OTFT of claim 1 wherein the back gate electrode is only connected to the front gate electrode or the source terminal.

15. An electronic device comprising an OTFT according to claim 1.

16. An active matrix display backplane comprising a plurality of OTFTs according to claim 1.

17. The active matrix display backplane of claim 16 wherein the back gate electrode of each of the plurality of OTFTs is only electrically connected to one of: the front gate electrode of the same OTFT and the source terminal of the same OTFT and is not connected to the front gate electrode or back gate electrode of any other of the plurality of OTFTs.

18. An active matrix display backplane comprising a combination of:
OTFTs according to claim 1 in which the front gate electrode is connected to the back gate electrode; and
OTFTs according to claim 1 in which the front gate electrode is connected to the source terminal.

19. An active matrix display backplane comprising:
a combination of:
OTFTs according to claim 1 in which the front gate electrode is connected to the back gate electrode; and
OTFTs according to claim 1 in which the front gate electrode is connected to the source terminal; and
a plurality of pixel OTFTs arranged in a regular array of rows and columns, each pixel OTFT arranged to control current to a pixel electrode, where each pixel OTFT comprises an OTFT according to claim 1 in which the back gate electrode is connected to the source terminal.

20. The active matrix display backplane comprising a combination of:
OTFTs according to claim 1 in which the front gate electrode is connected to the back gate electrode; and
OTFTs according to claim 1 in which the front gate electrode is connected to the source terminal; and
a plurality of pixel OTFTs arranged in a regular array of rows and columns, each pixel OTFT arranged to control current to a pixel electrode, where each pixel OTFT comprises an OTFT according to claim 1 in which the back gate electrode is connected to the source terminal; and
a driver circuit arranged to provide a voltage to a row or column of pixel OTFTs wherein the driver comprises an OTFT according to claim 1 in which the front gate electrode is connected to the back gate electrode.

21. A method of operating an electronic device comprising an OTFT according to claim 1 wherein the back gate is electrically connected to the front gate, the method comprising:
performing a conditioning routine in which a bias is applied to the OTFT to place the OTFT in a temporary condition in which the turn on voltage is negative; and
operating the electronic device while the OTFT is in the temporary condition.

22. A method of fabricating an OTFT, the method comprising the steps:
forming a back gate electrode on a substrate;
forming a source terminal and a drain terminal;
forming an organic semiconductor layer above the back gate and between the source and drain terminals, the organic semiconductor layer comprising an organic binder;
forming a front gate electrode above the organic semiconductor layer; and
forming an interconnect to connect the back gate electrode to one of: the front gate electrode and the source terminal.

23. The method of claim 22 wherein forming an organic semiconductor layer comprises depositing an organic semiconducting ink, the organic semiconducting ink comprising a polycrystalline small molecule organic semiconductor, an organic binder and a solvent, wherein the polycrystalline small molecule organic semiconductor preferably comprises a polyacene compound or moiety.

24. The method of claim 22 wherein forming a back gate electrode on the substrate comprises sputtering a metal film onto the substrate and etching the metal film to form the back gate electrode.

25. The method of claim 22 further comprising:
forming an organic cross-linked base layer on the surface of the back gate electrode and forming the drain terminal and the source terminal on the base layer.

26. The method of any of claim 22 further comprising forming an organic gate insulating layer on the organic semiconducting layer and forming the front gate electrode on the gate insulating layer, where the gate insulating layer preferably comprises a perfluoropolymer.

27. The method of claim 26 comprising forming a sputter resistance layer on the organic gate insulating layer, where the front gate electrode is then subsequently formed on the organic gate insulating layer, wherein the sputter resistance layer preferably comprises a cross-linked organic layer having a permittivity (k)>3.3 @ 1000 Hz.

28. The method of claim 22 further comprising:
forming a passivation layer to cover the front gate electrode and all layers between the front gate electrode and substrate;
etching a plurality of vias through the passivation layer and depositing a metal layer to provide a connection between:
the front gate electrode and back gate electrode; or
the back gate electrode and source terminal.
